(19) United States
(12) Patent Application Publication
(10) Pub. No.: US 2025/0318382 A1
(43) Pub. Date: Oct. 9, 2025

(54) DISPLAY PANEL AND DISPLAY DEVICE

(71) Applicant: HKC CORPORATION LIMITED, Shenzhen (CN)

(72) Inventors: Hongsong WANG, Shenzhen (CN); Haijiang YUAN, Shenzhen (CN)

(21) Appl. No.: 19/086,194

(22) Filed: Mar. 21, 2025

(30) Foreign Application Priority Data
Apr. 8, 2024 (CN) 202410414040.4

(51) Int. Cl. H10K 59/131; H10K 59/80

(52) U.S. Cl. CPC H10K 59/131; H10K 59/873

(57) ABSTRACT

A display panel and a display device are disclosed. The display panel includes a substrate and multiple pixel modules. The pixel modules are used for emitting light and display. The substrate is divided into multiple installation regions. Each pixel module is correspondingly installed in the respective installation region. The display panel further includes a pressing structure, which includes a lifting device and a cover piece. There are at least two lifting devices, respectively connected to both sides of the substrate. A top of each lifting device is connected to the cover piece. The lifting devices can drive the cover piece to rise and fall in a direction perpendicular to the substrate. After the pixel modules are installed, the lifting devices drive the cover piece to cover the multiple pixel modules and abut against the multiple pixel modules to lie in the same plane.

### CROSS-REFERENCE TO RELATED APPLICATIONS

This application claims the priority and benefit of Chinese patent application number 2024104140404, titled “Display Panel and Display Device” and filed Apr. 8, 2024 with China National Intellectual Property Administration, the entire contents of which are incorporated herein by reference.

### TECHNICAL FIELD

This application relates to the display field, and more particularly to a display panel and a display device.

### BACKGROUND

The description provided in this section is intended for the mere purpose of providing background information related to the present application but doesn't necessarily constitute prior art.

With the rapid development of display devices, OLED (Organic Light-Emitting Diode) display panels are becoming more and more popular because of their superior colors and image display effects. An OLED display panel can rely on each pixel module to emit light independently, so that one or more pixel modules can form display effects of different formats.

However, a large number of pixel modules may be required to form an OLED display panel, and each pixel module needs to be installed on the substrate. In order to increase the installation speed, a large number of pixel modules may be poured on the substrate first, and then each pixel module is installed to the specified position of the substrate. After multiple pixel modules are installed, they may have uneven heights due to installation errors, and it is difficult to ensure that the multiple pixel modules lie on the same plane, thereby affecting the display effect of the display panel and the overall viewing effect. Furthermore, it is time-consuming and laborious to adjust the positions of pixel modules with position errors one by one, which greatly reduces the assembly efficiency of the display panel.

Therefore, how to overcome the problem of uneven heights of multiple pixel modules due to installation errors thus improving the assembly efficiency of the display panel and ensuring the image display effect of the display panel has become an urgent problem to be solved in the art.

### SUMMARY

Embodiments of the present application disclose a display panel and a display device, the purpose of which is to solve the uneven heights problem of multiple pixel modules caused by installation errors, thereby improving the assembly efficiency of the display panel and ensuring the image display effect of the display panel.

Embodiments of the present application disclose a display panel, including a substrate and a plurality of pixel modules. The pixel modules are used for emitting light and display. The substrate is divided into a plurality of installation regions. Each pixel module is correspondingly installed in the respective installation region. The display panel further includes a pressing structure. The pressing structure includes a lifting device and a cover piece. There are at least two lifting devices, which are respectively connected to both sides of the substrate. A top of each lifting device is connected to the cover piece. The lifting devices are operative to drive the cover piece to rise and fall in a direction perpendicular to the substrate. When the pixel modules are installed, the lifting devices drive the cover piece to cover the plurality of pixel modules and abut the plurality of pixel modules to lie in the same plane so that the top sides of the plurality of pixel modules are flush with each other.

In some embodiments, the lifting device includes a housing and a lifting rod. The housing is an internally hollowed structure. The lifting rod is arranged in the housing. The lifting rod divides the housing into a first chamber and a second chamber, where the second chamber is located above the first chamber. The lower part of the housing includes a valve assembly, a first air flow channel, and a second air flow channel. The side wall of the housing includes a third air flow channel. The display panel further includes an air pump, which is disposed on a back of the substrate. One end of the second air flow channel is connected to the valve assembly, and the other end is connected to the first chamber. The air pump is connected to the valve assembly through the first air flow channel. One end of the third air flow channel is connected to the second chamber, and the other end is connected to the valve assembly. The bottom of the housing includes a first pressure relief channel corresponding to the position of the first chamber. The first pressure relief channel is communicated to the first chamber. A first pressure relief valve is disposed in the first pressure relief channel. A second pressure relief channel is disposed at a side wall of the housing corresponding to the position of the second chamber. The second pressure relief channel is communicated to the second chamber. A second pressure relief valve is disposed in the second pressure relief channel. A pressure relief rate of each of the first pressure relief valve and the second pressure relief valve is less than a pressure increase rate in the first chamber or the second chamber. Before the pixel modules are installed, the air pump is turned on, the valve assembly controls the first air flow channel to be communicated to the second air flow channel, and the third air flow channel is closed. After the pixel modules are installed, the air pump is turned on, the valve assembly controls the first air flow channel to be communicated to the third air flow channel, and the second air flow channel is closed.

In some embodiments, a receiving groove is disposed at a lower part of the housing. The valve assembly is disposed in the receiving groove. The valve assembly includes a knob, a first rotary piece, a second rotary piece, and a fixing piece. The fixing piece is connected to a groove wall of the receiving groove. The knob is embedded in the fixing piece and is rotatably connected to the fixing piece. The side of the knob adjacent to the second air flow channel is connected to the first rotary piece, and the side of the knob adjacent to the third air flow channel is connected to the second rotary piece. The first rotary piece and the second rotary piece separate the receiving groove into a first air cavity and a second air cavity. The first air cavity and the second air cavity are disposed opposite to each other. The first air cavity is arranged adjacent to the first air flow channel and is communicated to the first air flow channel. Before the pixel modules are installed, the knob drives the first rotary piece to communicate the second air flow channel with the first air cavity, and the second rotary piece cuts the third air flow channel off from the first air cavity. After the pixel modules are installed, the knob drives the second rotary piece to communicate the third air flow channel with the first air cavity, and the first rotary piece cuts the second air flow channel off from the first air cavity.

In some embodiments, an inner wall of the receiving groove includes a first limiting piece corresponding to the position of the first rotary piece. The inner wall of the receiving groove further includes a second limiting piece corresponding to the position of the second rotary piece. The first rotary piece includes a first limiting groove corresponding to the position of the first limiting piece. The second rotary piece includes a second limiting groove corresponding to the position of the second limiting piece. The first limiting piece is embedded in the first limiting groove. The second limiting piece is embedded in the second limiting groove. The width of the first limiting groove is greater than the width of the first limiting piece. The width of the second limiting groove is greater than the width of the second limiting piece. When the second air flow channel is communicated to the first air cavity, the first limiting piece abuts against the side of the first limiting groove adjacent to the first air cavity, and the second limiting piece abuts against the side of the second limiting groove adjacent to the second air cavity. When the third air flow channel is communicated to the first air cavity, the first limiting piece abuts against the side of the first limiting groove facing away from the first air cavity, and the second limiting piece abuts against the side of the second limiting groove facing away from the second air cavity.

In some embodiments, a lifting channel is disposed in a top of the housing, and the lifting channel extends in a direction perpendicular to the substrate. The lifting rod includes a supporting piece, a rod body, and an isolating piece. The supporting piece and the isolating piece are respectively connected to both ends of the rod body. The rod body is partially embedded in the lifting channel, and the supporting piece is extended outside the housing. The supporting piece is used to connect with the cover piece. The isolating piece is located in the housing, and divides the housing into a first chamber and a second chamber.

In some embodiments, a buffer piece is disposed at a bottom of the first chamber, and the buffer piece is connected to the inner wall of the housing. When the cover piece is covered on the pixel modules, the isolating piece abuts against the buffer piece.

In some embodiments, the cover piece includes a cover plate. The cover plate is made of a light-transmitting material. An orthographic projection area of the cover plate on the substrate is greater than or equal to an orthographic projection area of the plurality of installation regions on the substrate. A mounting piece is disposed on the supporting piece. A first connecting piece is disposed at a position of the cover plate corresponding to the mounting piece. The mounting piece is connected to the first connecting piece to fix the cover plate to the supporting piece.

In some embodiments, a plurality of retaining walls are arranged on the substrate, and the plurality of retaining walls are arranged in a crisscross pattern to divide the substrate into a plurality of array-arranged installation regions. An installation groove is disposed in each installation region. A shape of the installation groove matches a shape of the pixel module, and the pixel module is partially embedded in the respective installation groove. A height of the retaining wall is equal to a height of the portion of the pixel module exposed from the respective installation groove. After the pixel modules are installed, the lifting devices drive the cover piece to abut against a top surface of the retaining wall.

In some embodiments, the display panel further includes a hollow cover plate. An orthographic projection area of the hollow cover plate on the substrate is greater than or equal to an orthographic projection area of the plurality of installation regions on the substrate. The hollow cover plate defines a through hole corresponding to each installation region, and the area of the through hole is greater than the area of the pixel module. The hollow cover plate includes a second connecting piece corresponding to the mounting piece, and the second connecting piece is connected to the mounting piece to fix the hollow cover plate to the supporting piece. Before the pixel modules are installed, the lifting devices drive the hollow cover plate to rise to a preset height.

The embodiment of the present application further includes a display device, including a housing. The display device further includes the display panel described above, where the display panel is arranged in the housing.

The present application improves the structure of the display panel. By installing a lifting device on each of both sides of the substrate and connecting the lifting devices to the cover piece, the lifting devices can drive the cover piece to rise and fall in a direction perpendicular to the substrate. After multiple pixel modules are installed on the substrate, the lifting devices drive the cover piece to descend to abut against the multiple pixel modules, so that even if the multiple pixel modules are uneven after installation due to installation errors, they will be located in the same plane under the pressing of the cover piece, thus overcoming the uneven heights problem of multiple pixel modules caused by installation errors, thereby improving the assembly efficiency of the display panel and ensuring the image display effect of the display panel.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative efforts.

FIG. 1 is a schematic diagram of a first embodiment of a display panel of the present application.

FIG. 2 is a schematic diagram of a pixel module in the first embodiment of the display panel of the present application.

FIG. 3 is a schematic diagram of a substrate in the first embodiment of the display panel of the present application.

FIG. 4 is a schematic diagram of a lifting device in the first embodiment of the display panel of the present application.

FIG. 5 is a partial schematic diagram illustrating the assembly of the lifting device with a cover piece in the first embodiment of the display panel of the present application.

FIG. 6 is a schematic diagram of a lifting device in a second embodiment of the display panel of the present application.

FIG. 7 is a schematic diagram of a lifting device in a third embodiment of the display panel of the present application.

FIG. 8 is a schematic diagram of a fourth embodiment of the display panel of the present application.

FIG. 9 is a schematic diagram of a hollow cover plate in the fourth embodiment of the display panel of the present application.

FIG. 10 is a schematic diagram of an embodiment of a display device of the present application.

In the drawings: 10, display device; 100, display panel; 200, rear housing; 110, pixel module; 111, pixel driving circuit; 112, communication module; 113, control module; 114, base; 115, power receiving terminal; 116, first coil; 117, light-emitting layer; 118, encapsulating layer; 120, substrate; 121, power supply terminal; 122, second coil; 123, installation region; 124, installation groove; 125, retaining wall; 130, pressing structure; 131, lifting device; 132, housing; 133, first chamber; 134, buffer piece; 135, second chamber; 136, lifting channel; 140, receiving groove; 141, first air cavity; 142, second air cavity; 143, first limiting piece; 144, second limiting piece; 150, lifting rod; 151, supporting piece; 152, mounting piece; 153, rod body; 154, isolating piece; 160, valve assembly; 161, knob; 162, first rotary piece; 163, first limiting groove; 164, second rotary piece; 165, second limiting groove; 166, fixing piece; 170, first air flow channel; 171, second air flow channel; 172, third air flow channel; 173, air pump; 174, first pressure relief channel; 175, first pressure relief valve; 176, second pressure relief channel; 177, second pressure relief valve; 180, cover piece; 181, cover plate; 182, first connecting piece; 190, hollow cover plate; 191, through hole; 192, second connecting piece.

### DETAILED DESCRIPTION OF EMBODIMENTS

The present application is described in detail below with reference to the accompanying drawings and optional embodiments. It should be noted that, under the premise of no conflict, the embodiments or technical features described below can be arbitrarily combined to form new embodiments.

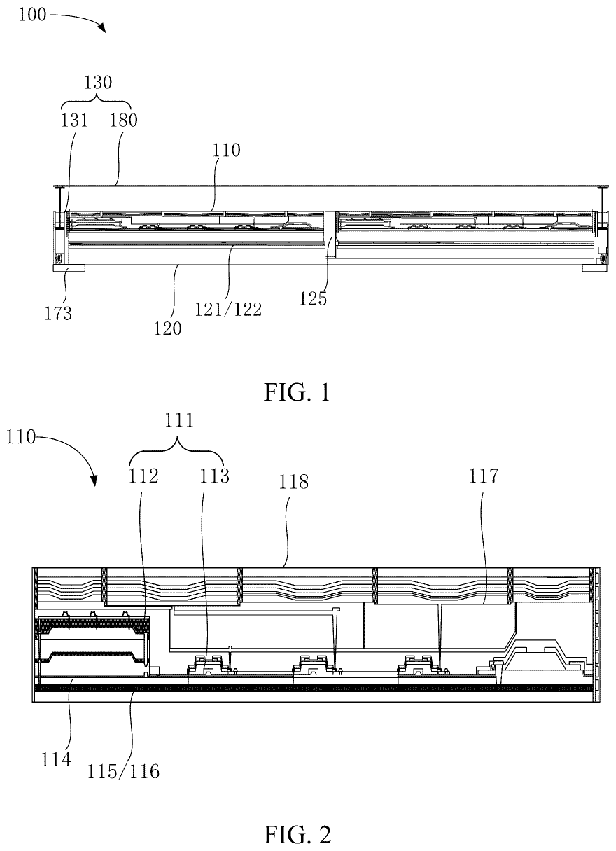

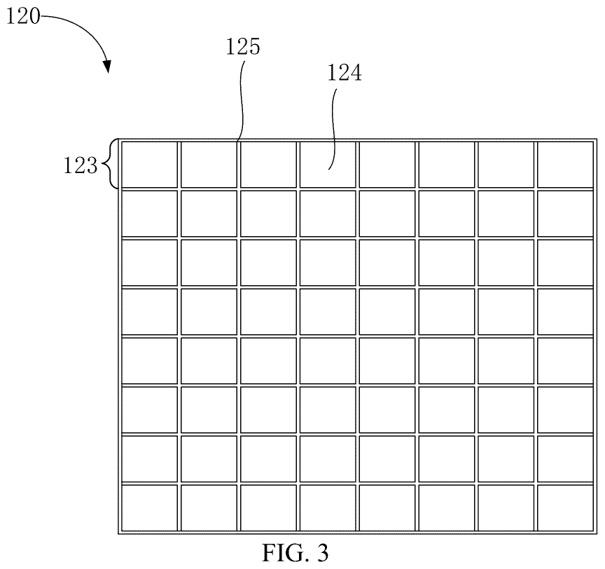

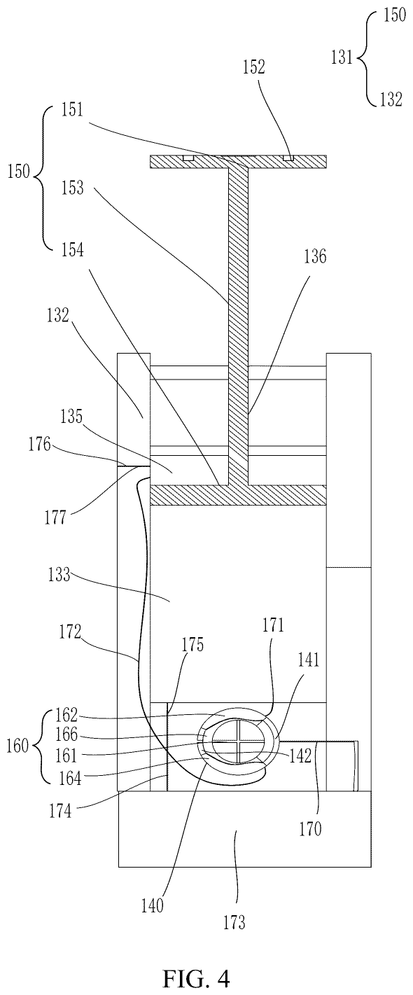

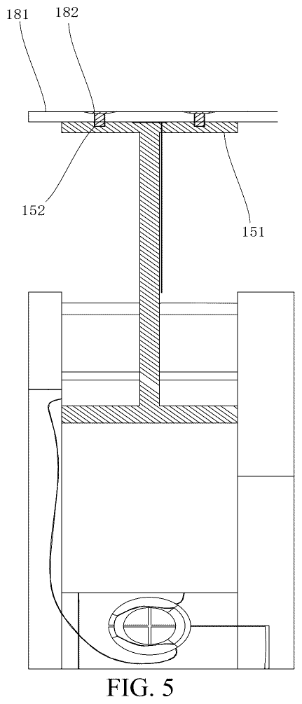

FIG. 1 is a schematic diagram of a first embodiment of a display panel of the present application. FIG. 2 is a schematic diagram of a pixel module in the first embodiment of the display panel of the present application. FIG. 3 is a schematic diagram of a substrate in the first embodiment of the display panel of the present application. FIG. 4 is a schematic diagram of a lifting device in the first embodiment of the display panel of the present application. FIG. 5 is a partial schematic diagram illustrating the assembly of the lifting device and a cover piece in the first embodiment of the display panel of the present application. As shown in FIG. 1 to FIG. 5, embodiments of the present application disclose a display panel 100, including a substrate 120 and a plurality of pixel modules 110. The pixel modules 110 are used for light-emission and display. The substrate 120 is divided into a plurality of installation regions 123. Each pixel module 110 is correspondingly installed in each respective installation region 123. The display panel 100 further includes a pressing structure 130. The pressing structure 130 includes a lifting device 131 and a cover piece 180. There are at least two lifting devices 131, and the at least two lifting devices 131 are connected to both sides of the substrate 120 respectively. Furthermore, the top of each lifting device 131 is connected to the cover piece 180. The lifting device 131 can drive the cover piece 180 to rise and fall in a direction perpendicular to the substrate 120. When the pixel modules 110 are installed, the lifting device 131 drives the cover piece 180 to cover tops of multiple pixel modules 110 and abut on the multiple pixel modules 110 to lie in the same plane so that the top sides of the plurality of pixel modules are flush with each other.

The present application improves the structure of the display panel 100. By installing a lifting device 131 on each of both sides of the substrate 120 and connecting the lifting devices 131 to the cover piece 180, the lifting devices 131 can drive the cover piece 180 to rise and fall in a direction perpendicular to the substrate 120. After multiple pixel modules 110 are installed on the substrate 120, the lifting devices 131 drive the cover piece 180 to descend to abut against the multiple pixel modules 110, so that even if the multiple pixel modules 110 are uneven after installation due to installation errors, they will be located in the same plane under the pressing of the cover piece 180 so that the top sides of the plurality of pixel modules are flush with each other, thus overcoming the uneven heights problem of multiple pixel modules 110 caused by installation errors, thereby improving the assembly efficiency of the display panel 100 and ensuring the image display effect of the display panel 100.

It should be noted that in the display panel 100 of the present application, each pixel module 110 may be displayed separately as a pixel of the display panel 100. Multiple sub-pixels on each pixel module 110 constitute a pixel. The multiple sub-pixels include a red light-emitting unit R, a green light-emitting unit G, and a blue light-emitting unit B. That is, only one pixel unit is included in each pixel module 110. One pixel unit includes a red sub-pixel, a green sub-pixel, and a blue sub-pixel. Three sub-pixels of different colors can display any color by adjustment to create different grayscale voltages. This is equivalent to each pixel unit on the display panel 100 forming a module, and the display panel 100 realized display through each modular pixel module 110.

Specifically, each pixel module 110 includes a pixel driving circuit 111, and the pixel driving circuit 111 drives the pixel module 110 to emit light and display. The pixel driving circuit 111 includes a communication module 112 and a control module 113. The communication module 112 is used to receive data signals. The control module 113 controls the pixel module 110 to emit light and display according to the data signal. The pixel module 110 includes a base 114, and a light-emitting layer 117 and an encapsulating layer 118 that are sequentially arranged on the base 114. A power receiving terminal 115 is arranged on the side of the base 114 facing away from the light-emitting layer 117. A power supply terminal 121 is arranged in the substrate 120 corresponding to the power receiving terminal 115. The power supply terminal 121 provides an electrical signal to the power receiving terminal 115 to power up the pixel driving circuit 111.

For example, when the signal transmission mode of the pixel module 110 is wireless transmission mode, the power receiving terminal 115 includes a first coil 116, and the power supply terminal 121 includes a second coil 122. Multiple power supply terminals 121 are disposed in one-to-one correspondence with the power receiving terminals 115 on the multiple pixel modules 110. The first coil 116 and the second coil 122 transmit signals wirelessly therebetween to realize the power supply to the pixel module 110.

Specifically, the communication module 112 includes a wireless receiving module, which is used to receive an external data signal and generate a data control signal according to the external signal and transmit it to the control module 113. In this embodiment, the signal transmission mode of the pixel module 110 may be a wireless transmission mode, for example, a wireless transmission module and a wireless receiving module are disposed externally to cooperate with each other. Take a WiFi module as an example, at least multiple WiFi receiving modules and one WiFi transmission module are included. Each pixel module 110 includes at least one WiFi receiving module, and each pixel module 110 adopts the WiFi module networking mode, and receives the above-mentioned external data signal through the wireless receiving module, thereby realizing the signal transmission of the pixel module 110 and controlling the pixel module 110 to emit light. Of course, in addition to the one-to-multiple method, wireless transmission may also be performed by setting multiple WiFi transmission modules to transmit data in a one-to-one manner.

Of course, the signal transmission of the pixel module 110 may also adopt a contact signal transmission method, for example, a bare metal gasket may be provided separately at a bottom of the pixel module 110 and in the corresponding installation region 123. When the pixel module 110 is installed in the installation region 123, the corresponding power receiving terminal 115 contacts the power supply end to achieve electrical connection. The foregoing data signals and other control signals may also adopt the above transmission method.

In addition, the present application enables the pixel modules 110 to be installed at the preset positions of the substrate 120 in a rapid manner, and facilitates the lifting devices 131 to drive the cover piece 180 to press the multiple pixel modules 110, so as to adjust the multiple pixel modules 110 to be situated in the same plane so that the top sides of the plurality of pixel modules are flush with each other. The present application further improves the substrate 120 and the pixel module 110, where the specific improvements are as follows.

A plurality of retaining walls 125 are arranged on the substrate 120, and the plurality of retaining walls 125 are arranged in a crisscross pattern to divide the substrate 120 into a plurality of array-arranged installation regions 123. An installation groove 124 is defined in the installation region 123, and the shape of the installation groove 124 matches the shape of the pixel module 110. The pixel module 110 is partially embedded in the installation groove 124. The height of the retaining wall 125 is equal to the height of the portion of the pixel module 110 exposed from the installation groove 124. After the pixel modules 110 are installed, the lifting devices 131 drives the cover piece 180 to abut against the top surface of the retaining wall 125.

In this embodiment, a plurality of retaining walls 125 are first arranged on the substrate 120, and the surface of the substrate 120 is divided into a plurality of installation regions 123 by the retaining walls 125. An installation groove 124 is dug in each installation region 123, and the installation groove 124 is used to form a preset installation position for the pixel module 110. When installing the pixel modules 110 on the substrate 120, the installation position of each pixel module 110 may be observed more conveniently. It is only needed to embed the pixel module 110 into the installation groove 124, and a part of the pixel module 110 is embedded in the interior of the installation groove 124, so that the pixel module 110 is limited by the installation groove 124 and the pixel module 110 is not easy to shake, and the problem of the pixel module 110 falling off the substrate 120 is improved, which is conducive to improving the stability of the connection between the pixel module 110 and the substrate 120.

The other part is exposed outside the installation groove 124, which is convenient for pressing the cover piece 180, so that the cover piece 180 can be more easily contacted with the multiple pixel modules 110. When the pixel modules 110 are initially installed in the installation groove 124 of the substrate 120, the pixel modules 110 may have uneven heights in the installation grooves 124 due to the problem of installation errors. At this time, the lifting devices 131 are used to drive the cover piece 180 to descend. Since the side of the cover piece 180 facing the pixel module 110 is a horizontal plane, the cover piece 180 will first contact the pixel module 110 that is located higher in the installation groove 124 during the descending process, and abut against the pixel module 110 to press it downward, so that the pixel module 110 that is located comparatively higher is completely pressed to be in contact with the bottom of the respective installation groove 124, thereby ensuring that the multiple pixel modules 110 are located on the same horizontal plane. When the multiple pixel modules 110 are on the same horizontal plane, the cover piece 180 just abuts against the top surfaces of the retaining walls 125, and restricts and encloses multiple pixel modules 110 in the space surrounded by the retaining walls 125, so that the pixel modules 110 will not fall from the substrate 120, further enhancing the overall structural stability of the display panel 100.

The lifting device 131 in the present application includes a housing 132 and a lifting rod 150. The housing 132 is an internally hollowed structure. The lifting rod 150 is arranged in housing 132. The lifting rod 150 divides housing 132 into a first chamber 133 and a second chamber 135. The second chamber 135 is located above the first chamber 133. The valve assembly 160, the first air flow channel 170, and the second air flow channel 171 are arranged at the lower part of the housing 132. The third air flow channel 172 is arranged on ta he side wall of the housing 132. The display panel 100 further includes an air pump 173, which is arranged on a back of the substrate 120. One end of the second air flow channel 171 is connected to the valve assembly 160, and the other end is connected to the first chamber 133. The air pump 173 is connected to the valve assembly 160 through the first air flow channel 170. One end of the third air flow channel 172 is connected to the second chamber 135, and the other end is connected to the valve assembly 160. A first pressure relief channel 174 is arranged at a bottom of the housing 132 corresponding to the position of the first chamber 133. The first pressure relief channel 174 is connected to the first chamber 133. A first pressure relief valve 175 is disposed in the first pressure relief channel 174. A second pressure relief channel 176 is disposed at a side wall of housing 132 corresponding to the position of second chamber 135. The second pressure relief channel 176 is connected to the second chamber 135. A second pressure relief valve 177 is disposed in the second pressure relief channel 176. A pressure relief rate of each of the first pressure relief valve 175 and the second pressure relief valve 177 is less than a pressure increase rate in the first chamber 133 or the second chamber 135. Before pixel module 110 is installed, the air pump 173 is opened, the valve assembly 160 controls the first air flow channel 170 and the second air flow channel 171 to be opened, and controls the third air flow channel 172 to be closed. After the pixel module 110 is installed, the air pump 173 is turned on, the valve assembly 160 controls the first air flow channel 170 and the third air flow channel 172 to be opened, and controls the second air flow channel 171 to be closed.

The present application mainly utilizes the pressure difference generated by the changes of pressures between the first chamber 133 and the second chamber 135 to push the lifting rod 150 of the lifting device 131 to rise or fall in the housing 132, thereby driving the cover piece 180 to fall and cover the pixel module 110, so that multiple pixel modules 110 are located on the same horizontal plane.

The specific working principle is as follows. Before installing the multiple pixel modules 110 on substrate 120, first use the valve assembly 160 to communicate the first air flow channel 170 with the second air flow channel 171, and close the third air flow channel 172. Then open the air pump 173, which first supplies air to the first air flow channel 170. The gas enters the first chamber 133 through the first air flow channel 170 and the second air flow channel 171. Since the gas continues to enter the first chamber 133, the air pressure of the first chamber 133 is greater than the air pressure of the second chamber 135. Under the action of the air pressure difference, the lifting rod 150 is pushed upward. While the lifting rod 150 moves upward, it compresses the space of the second chamber 135, and the gas in the second chamber 135 is discharged to the external environment through the second pressure relief valve 177 in the second pressure relief channel 176. Thereby, the lifting rod 150 continuously compresses the space of the second chamber 135 and rises steadily, without being affected by the relatively large air pressure resistance in the second chamber 135, and drives the cover piece 180 to move upward at the same time, so that a preset distance is created between the cover piece 180 and the substrate 120, providing enough space for installing the pixel modules 110.

After the multiple pixel modules 110 are installed on substrate 120, the valve assembly 160 is used to communicate the first air flow channel 170 and the third air flow channel 172, and the second air flow channel 171 is closed. The gas provided by the air pump 173 enters the second chamber 135 through the first air flow channel 170 and the third air flow channel 172. At this time, the first chamber 133 no longer takes in air, and the gas in the first chamber 133 is gradually discharged to the external environment through the first pressure relief valve 175 in the first pressure relief channel 174. Since the gas continuously enters the second chamber 135, the air pressure in the second chamber 135 is greater than the air pressure in the first chamber 133. Under the action of the air pressure difference, the lifting rod 150 is pushed downward. While the lifting rod 150 moves downward, it compresses the space of the first chamber 133, and the gas in the first chamber 133 is accelerated to be discharged from the first pressure relief valve 175 during the compression process. Thus, the lifting rod 150 can continuously compress the space of the first chamber 133 and descend relatively smoothly and quickly, and is not easily affected by the resistance of the relatively high air pressure in the first chamber 133, until the cover piece 180 is driven to cover the multiple pixel modules 110, so that the multiple pixel modules 110 located at uneven heights are on the same horizontal plane.

Furthermore, a lifting channel 136 is provided in a top of the housing 132, and the lifting channel 136 extends in a direction perpendicular to the substrate 120. The lifting rod 150 includes a supporting piece 151, a rod body 153, and an isolating piece 154. The supporting piece 151 and the isolating piece 154 are respectively connected to both ends of the rod body 153. The rod body 153 is partially embedded in the lifting channel 136, and the supporting piece 151 is extended to the outside of the housing 132. The supporting piece 151 is used to connect with the cover piece 180. The isolating piece 154 is located in the housing 132, and divides the housing 132 into a first chamber 133 and a second chamber 135.

The supporting piece 151 and the isolating piece 154 in the present application may each be a plate-like structure. The supporting piece 151 of the plate-like structure is used to connect with the cover piece 180. It can be understood that in order to ensure that the cover piece 180 presses multiple pixel modules 110 to lie in the same plane so that the top sides of the plurality of pixel modules are flush with each other, the side of the cover piece 180 facing the pixel module 110 may be a horizontal plane.

When the side of the cover piece 180 facing the supporting piece 151 is flat, the supporting piece 151 can more easily keep the cover piece 180 in a horizontal state. The isolating piece 154 is located in the housing 132, dividing the space in the housing 132 into the first chamber 133 and the second chamber 135. By changing the air pressure in the first chamber 133 or the second chamber 135, the isolating piece 154 located between the two chambers is pushed under the action of the air pressure difference, thereby achieving the overall rise or fall of the lifting rod 150.

The supporting piece 151 and the isolating piece 154 are respectively connected to the two ends of the rod body 153 to form an I-shaped lifting rod 150, which can not only stably support the cover piece 180, but also move smoothly in the housing 132. The rod body 153 of the lifting rod 150 is partially embedded in the lifting channel 136 at the top of the housing 132, so that when the lifting rod 150 rises or falls, the rod body 153 always moves in the lifting channel 136, and the lifting channel 136 is used to limit the rod body 153, thereby ensuring that the lifting rod 150 may only rise or fall in a direction perpendicular to the substrate 120 without position deviation, and ensuring that the lifting rod 150 can drive the cover piece 180 to rise or fall smoothly, so that the cover piece 180 always remains horizontal during the rising or falling process, which is conducive to using the cover piece 180 to press multiple uneven pixel modules 110 to lie on the same horizontal plane.

In addition, in order to enable the valve assembly 160 to better control the opening or closing of each air flow channel when the lifting rod 150 needs to rise or fall, thereby controlling the air pressure change of the first chamber 133 or the second chamber 135 to generate an air pressure difference so that the lifting rod 150 can rise or fall under the action of the air pressure difference, the present application further designs the structure of the valve assembly 160 as follows.

A receiving groove 140 is disposed at a lower part of housing 132. The valve assembly 160 is disposed in the receiving groove 140. The valve assembly 160 includes a knob 161, a first rotary piece 162, a second rotary piece 164, and a fixing piece 166. The fixing piece 166 is connected to a groove wall of the receiving groove 140. The knob 161 is embedded in the fixing piece 166 and is rotatably connected to the fixing piece 166. The side of the knob 161 adjacent to the second air flow channel 171 is connected to the first rotary piece 162, and the side of the knob 161 adjacent to the third air flow channel 172 is connected to the second rotary piece 164. The first rotary piece 162 and the second rotary piece 164 separate the receiving groove 140 into a first air cavity 141 and a second air cavity 142. The first air cavity 141 and the second air cavity 142 are disposed opposite to each other. The first air cavity 141 is arranged adjacent to the first air flow channel 170 and is communicated to the first air flow channel 170. Before the pixel modules 110 are installed, the knob 161 drives the first rotary piece 162 to communicate the second air flow channel 171 with the first air cavity 141, and the second rotary piece 164 cuts off the communication between the third air flow channel 172 from the first air cavity 141. After the pixel modules 110 are installed, the knob 161 drives the second rotary piece 164 to communicate the third air flow channel 172 with the first air cavity 141, and the first rotary piece 162 cuts off the communication between the second air flow channel 171 from the first air cavity 141.

The valve assembly 160 of the present application mainly drives the first rotary piece 162 and the second rotary piece 164 to rotate by rotating the knob 161. The first rotary piece 162 is used to control the communication or shutoff between the first air flow channel 170, the first air cavity 141, and the second air flow channel 171. The second rotary piece 164 is used to control the communication or shutoff between the first air flow channel 170, the first air cavity 141, and the third air flow channel 172, thereby controlling the gas of the air pump 173 to enter the first chamber 133 or the second chamber 135, so that the two chambers have pressure differences in different directions.

The specific working principle is as follows. When the lifting rod 150 needs to rise, it is only required to use the knob 161 to rotate the second rotary piece 164 to the connection port between the first air cavity 141 and the third air flow channel 172, so that the second rotary piece 164 blocks the connection port between the first air cavity 141 and the third air flow channel 172, thereby isolating the air intake of the second chamber 135. At the same time, the first rotary piece 162 is rotated to avoid the connection port position between the first air cavity 141 and the second air flow channel 171, so that the first air cavity 141 and the second air flow channel 171 are communicated, so that the gas of the air pump 173 in turn enters the first air cavity 141 and the second air flow channel 171 from the first air flow channel 170, and finally enters the first chamber 133, thereby increasing the air pressure in the first chamber 133. Under the action of the air pressure difference between the first chamber 133 and the second chamber 135, the lifting rod 150 is pushed up.

When the lifting rod 150 needs to descend, the first rotary piece 162 is rotated to the connection port between the first air cavity 141 and the second air flow channel 171 by using the knob 161, so that the first rotary piece 162 blocks the connection port between the first air cavity 141 and the second air flow channel 171, thereby isolating the air intake of the first chamber 133. At the same time, the second rotary piece 164 is rotated to avoid the connection port between the first air cavity 141 and the third air flow channel 172, so that the first air cavity 141 and the third air flow channel 172 are communicated, so that the gas of the air pump 173 in turn enters the first air cavity 141, the third air flow channel 172 from the first air flow channel 170, and finally enters the second chamber 135, thereby increasing the air pressure in the second chamber 135. The lifting rod 150 is therefore pushed downward by the air pressure difference between the second chamber 135 and the first chamber 133.

In order to enable the lifting rod 150 to drive the cover piece 180 to cover the pixel module 110 smoothly after the lifting rod 150 is lowered, and to enable multiple pixel modules 110 that have uneven heights due to installation errors to be located in the same plane under the pressing of the cover piece 180 so that the top sides of the plurality of pixel modules are flush with each other, the present application further designs the cover piece 180 as follows.

Specifically, the cover piece 180 includes a cover plate 181, and the cover plate 181 is made of a light-transmitting material. An orthogonal projection area of the cover plate 181 on the substrate 120 is greater than or equal to an orthogonal projection area of the multiple installation regions 123 on the substrate 120. The supporting piece 151 includes a mounting piece 152. The cover plate 181 includes a first connecting piece 182 at a position corresponding to the mounting piece 152. The mounting piece 152 is connected to the first connecting piece 182, thereby fixing the cover plate 181 to the supporting piece 151.

In order to ensure that after the cover plate 181 covers the multiple pixel modules 110, the pixel modules 110 can emit light normally without affecting the overall display effect of the display panel 100, the cover plate 181 in the present application may be made of glass material or other plastic materials with a relatively high light transmittance.

The orthographic projection area of the cover plate 181 on the substrate 120 is greater than or equal to the orthographic projection area of the multiple installation regions 123 on the substrate 120, so that the cover plate 181 can cover all the pixel modules 110 as much as possible, and achieve full-surface pressing of the multiple pixel modules 110, which is conducive to quickly adjusting the installation positions of the pixel modules 110 and making the multiple pixel modules 110 lie in the same plane as a whole so that the top sides of the plurality of pixel modules are flush with each other, thereby improving the assembly efficiency of the display panel 100 and improving the display effect of the display panel 100.

It should be noted that, since the present application adopts the lifting device 131 to drive the cover plate 181 to rise and fall to cover multiple pixel modules 110, the lifting device 131 and the cover plate 181 may also be detachably connected. For example, the mounting piece 152 of the lifting device 131 may be a screw hole, and the corresponding first connecting piece 182 of the cover plate 181 may also be a screw hole, and the cover plate 181 and the lifting device 131 are fixed together by screws. In one implementation, the cover plate 181 may be installed on the lifting device 131 before the pixel modules 110 are mounted. Then the lifting device 131 is used to lift the cover plate 181 to a preset height relative to the substrate 120 before the pixel modules 110 are installed, so as to leave enough space for installing the pixel modules 110. Then the multiple pixel modules 110 are installed on the substrate 120. Finally, the lifting device 131 is used to drive the cover plate 181 to move downward to cover the multiple pixel modules 110, so that the multiple pixel modules 110 that have uneven heights due to installation errors are placed on the same plane so that the top sides of the plurality of pixel modules are flush with each other. Alternatively, after the multiple pixel modules 110 are installed on the substrate 120, the cover plate 181 is installed on the lifting device 131, and the lifting device 131 is used to drive the cover plate 181 to move downward to cover the multiple pixel modules 110. The specific operations may be carried out depending on actual needs. Furthermore, when the cover plate 181 is damaged, it may be disassembled and replaced individually from the lifting device 131, which is conducive to cost saving.

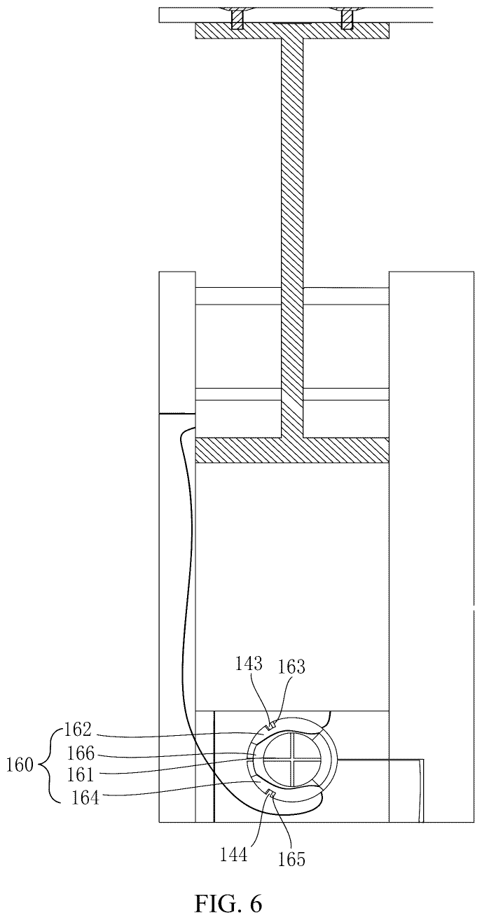

FIG. 6 is a schematic diagram of a lifting device in a second embodiment of the display panel of the present application. As shown in FIG. 6, the embodiment shown in FIG. 6 is an improvement based on FIG. 4. An inner wall of the receiving groove 140 includes a first limiting piece 143 corresponding to the position of the first rotary piece 162. The inner wall of the receiving groove 140 includes with a second limiting piece 144 corresponding to the position of the second rotary piece 164. The first rotary piece 162 includes a first limiting groove 163 corresponding to the position of the first limiting piece 143. The second rotary piece 164 includes a second limiting groove 165 corresponding to the position of the second limiting piece 144. The first limiting piece 143 is embedded in the first limiting groove 163, and the second limiting piece 144 is embedded in the second limiting groove 165. The width of the first limiting groove 163 is greater than the width of the first limiting piece 143. The width of the second limiting groove 165 is greater than the width of the second limiting piece 144. When the second air flow channel 171 is communicated to the first air cavity 141, the first limiting piece 143 abuts against the side of the first limiting groove 163 adjacent to the first air cavity 141, and the second limiting piece 144 abuts against the side of the second limiting groove 165 adjacent to the second air cavity 142. When the third air flow channel 172 is communicated to the first air cavity 141, the first limiting piece 143 abuts against the side of the first limiting groove 163 facing away from the first air cavity 141, and the second limiting piece 144 abuts against the side of the second limiting groove 165 facing away from the second air cavity 142.

The present embodiment is different from the previous embodiment in that, in the present embodiment, a first limiting piece 143 and a second limiting piece 144 are disposed on the inner wall of the receiving groove 140, and a first limiting groove 163 and a second limiting groove 165 are defined at the positions of the first rotary piece 162 and the second rotary piece 164 corresponding to the first limiting piece 143 and the second limiting piece 144 respectively. Furthermore, since the widths of the first limiting groove 163 and the second limiting groove 165 are both greater than the widths of the first limiting piece 143 and the second limiting piece 144 respectively, the first limiting piece 143 and the second limiting piece 144 can be relatively displaced within the first limiting groove 163 and the second limiting groove 165 respectively, that is, the rotation range of the first rotary piece 162 and the second rotary piece 164 driven by controlling the knob 161 without affecting the rotation of the knob 161.

When the lifting rod 150 needs to rise, the second air flow channel 171 needs to be communicated to the first air cavity 141. At this time, the knob 161 of the valve assembly 160 needs to be rotated. When the knob 161 drives the first rotary piece 162 to rotate until that the first limiting piece 143 abuts against the side of first limiting groove 163 adjacent to first air cavity 141 and that the first rotary piece 162 just avoids the connection port between the first air cavity 141 and the second air flow channel 171, and drives the second rotary piece 164 to rotate until that the second limiting piece 144 abuts against the side of the second limiting groove 165 adjacent to the second air cavity 142, and that the second rotary piece 164 just blocks the connection port between the third air flow channel 172 and the first air cavity 141, the second air flow channel 171 is communicated to the first air cavity 141. The first rotary piece 162 and the second rotary piece 164 cannot continue to rotate, so that the entire valve assembly 160 is maintained in a state of connecting the first chamber 133 for air intake. When the lifting rod 150 needs to be lowered, the third air flow channel 172 needs to be connected to the first air cavity 141, and the knob 161 of the valve assembly 160 needs to be rotated. When knob 161 drives first rotary piece 162 to rotate to such a position that the first limiting piece 143 abuts against the side of the first limiting groove 163 facing away from the first air cavity 141 and that the first rotary piece 162 just blocks the connection port between the first air cavity 141 and the second air flow channel 171, and drives the second rotary piece 164 to rotate to such a position that the second limiting piece 144 abuts against the side of the second limiting groove 165 facing away from the second air cavity 142, then the second rotary piece 164 just avoids the connection port between the third air flow channel 172 and the first air cavity 141. At this time, the third air flow channel 172 is communicated to the first air cavity 141, and the first rotary piece 162 and the second rotary piece 164 will not continue to rotate, so that the entire valve assembly 160 is maintained in a state of connecting the second chamber 135 for air intake.

That is, in this embodiment, the first limiting piece 143 and the second limiting piece 144 cooperate with the first limiting groove 163 and the second limiting groove 165 respectively, so that the knob 161 drives the first rotary piece 162 and the second rotary piece 164 to rotate to the specified positions without excessive rotation, thereby ensuring the stability of the valve assembly 160 controlling the air intake of the first chamber 133 or the second chamber 135.

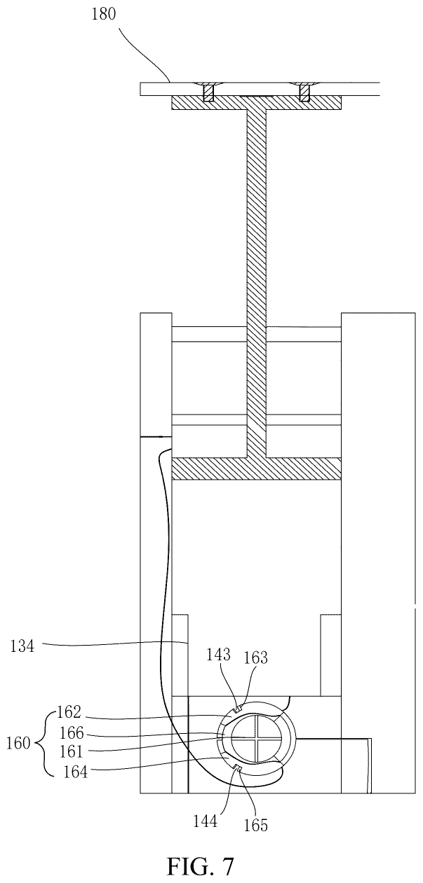

FIG. 7 is a schematic diagram of a lifting device in a third embodiment of the display panel of the present application. As shown in FIG. 7, the embodiment shown in FIG. 7 is an improvement based on FIG. 6. A buffer piece 134 is disposed at a lower part of the first chamber 133. The buffer piece 134 is connected to the inner wall of the housing 132. When the cover piece 180 covers the pixel modules 110, the isolating piece 154 abuts against the buffer piece 134.

The present embodiment is different from the previous embodiment in that a buffer piece 134 is disposed on the inner wall of the housing 132 located at the lower part of the first chamber 133. When the cover piece 180 covers the pixel modules 110, the isolating piece 154 of the lifting rod 150 just contacts the buffer piece 134. The elastic buffer pieceing force of the buffer piece 134 is used to alleviate the impact force generated when the lifting rod 150 descends, so that the lifting rod 150 remains stable as a whole during the process of the cover piece 180 descending and contacting the pixel modules 110, thereby enhancing the overall stability of the lifting device. In addition, the lifting rod 150 is effectively prevented from excessively descending, otherwise resulting in the lifting rod 150 driving the cover piece 180 to excessively press down on the pixel modules 110, causing the pixel modules 110 to be damaged, which is beneficial to prolonging the service life of the pixel module 110 and improving the yield rate of assembling the display panels 100.

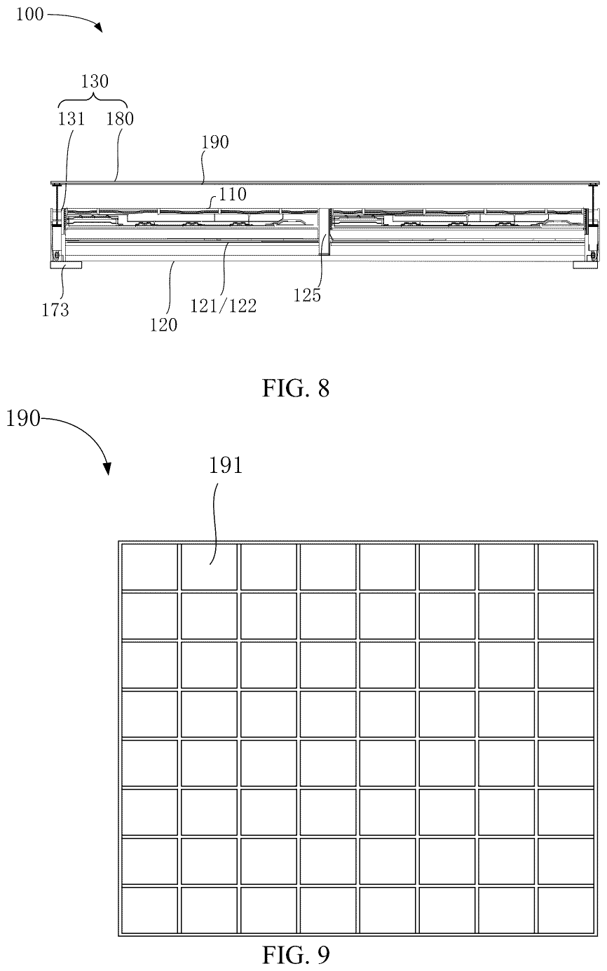

FIG. 8 is a schematic diagram of a fourth embodiment of the display panel of the present application. FIG. 9 is a schematic diagram of a hollow cover plate in the fourth embodiment of the display panel of the present application. As shown in FIG. 8 and FIG. 9, the display panel 100 further includes a hollow cover plate 190. The orthographic projection area of the hollow cover plate 190 on the substrate 120 is greater than or equal to the orthographic projection area of the multiple installation regions 123 on the substrate 120. The hollow cover plate 190 includes a through hole 191 corresponding to the position of each installation region 123. The area of the through hole 191 is greater than the area of the pixel module 110. The hollow cover plate 190 includes a second connecting piece 192 corresponding to the mounting piece 152. The second connecting piece 192 is connected to the mounting piece 152 to fix the hollow cover plate 190 to the supporting piece 151. Before the pixel modules 110 are installed, the lifting device 131 drives the hollow cover plate 190 to rise to a preset height.

The present embodiment is different from the previous embodiment in that, in the present embodiment a hollow cover plate 190 is additionally disposed on the lifting device 131. A plurality of through holes 191 are defined in the hollow cover plate 190, so that the hollow cover plate 190 as a whole forms a hollow cover plate 190 structure. Before installing a plurality of pixel modules 110, the hollow cover plate 190 may be first installed on the mounting piece 152 of the lifting device 131 through the second connecting piece 192. The second connecting piece 192 may be a screw hole pre-opened in the hollow cover plate 190, and the mounting piece 152 of the lifting device 131 may also be a screw hole. Then, the two screw holes are fixed by a screw, so that the hollow cover plate 190 is installed on the lifting device 131. Then, driven by the lifting device 131, the hollow cover plate 190 is lifted to a preset height relative to the substrate 120, so that the hollow cover plate 190 may provide a certain space for the installation of the pixel modules 110.

When multiple pixel modules 110 are poured from over of substrate 120 in order to quickly install the multiple pixel modules 110, they will pass through the through holes 191 of hollow cover plate 190 and fall onto substrate 120 when the multiple pixel modules 110 fall from over hollow cover plate 190, so that the normal pouring of the multiple pixel modules 110 on substrate 120 will not be affected. At the same time, when the multiple pixel modules 110 bounce after contacting the substrate 120, they will be blocked by the hollow cover plate 190. That is, the hollow cover plate 190 is used to restrict the multiple pixel modules 110 between the hollow cover plate 190 and the substrate 120 to prevent the pixel modules 110 from falling outside the substrate 120, thereby effectively improving the installation efficiency of the pixel modules 110.

After the multiple pixel modules 110 are installed on substrate 120, the cover piece 180 may then be installed on top of the hollow cover plate 190. When the cover piece 180 is a cover plate 181 made of a light-transmitting material, such as a cover plate 181 made of glass, the first connecting piece 182 on the cover plate 181 may also be a screw hole pre-opened in the cover plate 181. The cover plate 181 and the hollow cover plate 190 may be installed together on the lifting device 131 by passing the same screw through the corresponding screw holes of the cover plate 181 and the hollow cover plate 190. Then the hollow cover plate 190 and the cover piece 180 may be simultaneously driven to move downward by the lifting device 131.

In this embodiment, the thickness of the hollow cover plate 190 is less than or equal to the portion of the pixel module 110 exposed from the substrate 120. When the lifting device 131 drives the hollow cover plate 190 and the cover piece 180 to descend simultaneously, the portion of the pixel module 110 exposed from the substrate 120 will first enter the through hole 191 of the hollow cover plate 190. Then the top surface of the pixel module 110 will contact the cover piece 180. When the cover piece 180 is a cover plate 181 made of a light-transmitting material, the side of the cover plate 181 facing the pixel module 110 is a horizontal plane. Therefore, under the pressing of the cover piece 180, even if the multiple pixel modules 110 have uneven heights after installation due to installation errors, they will be located in the same plane due to the pressing of the cover piece 180 so that the top sides of the plurality of pixel modules are flush with each other, thus solving the uneven heights problem of the multiple pixel modules 110 caused by the installation errors, thereby improving the assembly efficiency of the display panel 100 and ensuring the image display effect of the display panel 100.

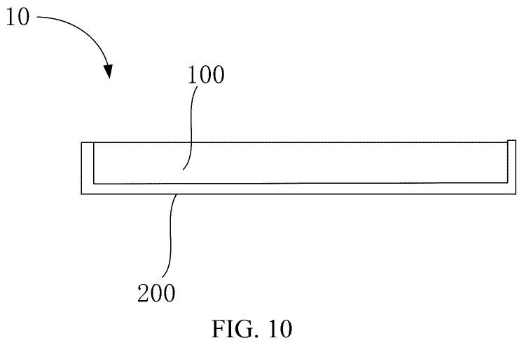

FIG. 10 is a schematic diagram of an embodiment of a display device of the present application. As shown in FIG. 10, embodiments of the present application further includes a display device 10, including a rear housing 200, and further includes the above-mentioned display panel 100. The display panel 100 is arranged in the rear housing 200. The rear housing 200 is used to protect the display panel 100 from being damaged by external impact, and may also effectively solve the problem of corrosion inside the display panel 100 caused by intrusion of external water vapor, which helps to extend the service life of the display device 10.

The display device 10 of the present application is mainly intended for a display device 10 having an OLED (Organic Light-Emitting Diode) display panel 100, such as a mobile phone, a computer, a television, etc. The present application does not specifically limit the type of the display device 10. Furthermore, in the present application, the display panel 100 in the display device 10 is mainly composed of a plurality of pixel modules 110 that can emit light independently.

After assembling multiple pixel modules 110 on the substrate 120, the multiple pixel modules 110 may be installed unevenly on substrate 120 due to installation errors, affecting the display effect of display panel 100 and the overall viewing effects of the display device 10.

Based on the above problems, the present application improves the display panel 100 in the display device 10. By installing a lifting device 131 on each of both sides of the substrate 120 and connecting the lifting devices 131 with the cover piece 180, the lifting devices 131 may drive the cover piece 180 to rise and fall in a direction perpendicular to the substrate 120. After multiple pixel modules 110 are installed on the substrate 120, the lifting devices 131 drive the cover piece 180 to descend to abut against the multiple pixel modules 110, so that even if the multiple pixel modules 110 have uneven heights after installation due to installation errors, they will be located in the same plane under the pressing of the cover piece 180 so that the top sides of the plurality of pixel modules are flush with each other, thus solving the uneven heights problem of multiple pixel modules 110 caused by installation errors, thereby improving the assembly efficiency of the display panel 100, ensuring the image display effect of the display panel 100, and improving the quality of the display device 10.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A display panel, comprising a substrate and a plurality of pixel modules, wherein the plurality of pixel modules are used for emitting light for display, wherein the substrate is divided into a plurality of installation regions, and wherein each of the plurality of pixel modules is installed in the respective installation region;
wherein the display panel further comprises a pressing structure, wherein the pressing structure comprises at least two lifting devices and a cover piece, wherein the at least two lifting devices are respectively connected to two sides of the substrate;
wherein a top of each of the at least two lifting devices is connected to the cover piece, and wherein the at least two lifting devices are operative to drive the cover piece to rise and fall in a direction perpendicular to the substrate;
wherein in response to the plurality of pixel modules being installed, the at least two lifting devices are operative to drive the cover piece to cover the plurality of pixel modules and abut against the plurality of pixel modules to lie in a same plane so that top surfaces of the plurality of pixel modules are flush with each other.

2. The display panel as recited in claim 1, wherein each of the plurality of pixel modules comprises a pixel driving circuit configured to drive the pixel module to emit light and display; wherein the pixel driving circuit comprises a communication module and a control module, wherein the communication module is used to receive a data signal, and the control module is configured to control the pixel module to emit light and display according to the data signal;
wherein each of the plurality of pixel modules comprises a base, and a light-emitting layer and an encapsulating layer that are sequentially disposed on the base; wherein the base comprises a power receiving terminal on a side facing away from the light-emitting layer, wherein the substrate comprises a power supply terminal corresponding to the power receiving terminal; wherein the power supply terminal is configured to provide an electrical signal to the power receiving terminal to supply power to the pixel driving circuit.

3. The display panel as recited in claim 2, wherein the power receiving terminal comprises a first coil, wherein the power supply terminal comprises a second coil, wherein there is disposed a plurality of the power supply terminals that are disposed in a one-to-one correspondence with a plurality of the power receiving terminals on the plurality of pixel modules; wherein the first coil and the second coil are operative to supply power to the respective pixel module by means of wirelessly transmitting a signal.

4. The display panel as recited in claim 2, wherein the communication module comprises a wireless receiving module, used to receive an external data signal and generate a data control signal based on the external data signal and transmit the data control signal to the control module.

5. The display panel as recited in claim 1, wherein each of the at least two lifting devices comprises a housing and a lifting rod, wherein the housing is an internally hollowed structure, wherein the lifting rod is disposed in the housing and divides the housing into a first chamber and a second chamber, wherein the second chamber is located above the first chamber;
wherein there is disposed a valve assembly, a first air flow channel, and a second air flow channel at a lower part of the housing; wherein there is disposed a third air flow channel in a side wall of the housing; wherein the display panel further includes an air pump disposed on a side of the substrate facing away from the plurality of pixel modules; wherein one end of the second air flow channel is communicated to the valve assembly, and wherein another end of the second air flow channel is communicated to the first chamber; wherein the air pump is connected to the valve assembly through the first air flow channel; wherein one end of the third air flow channel is communicated to the second chamber, and another end is communicated to the valve assembly;
wherein there is disposed a first pressure relief channel at a bottom of the housing corresponding to a position of the first chamber; wherein the first pressure relief channel is communicated to the first chamber; wherein there is disposed a first pressure relief valve in the first pressure relief channel, and wherein there is disposed a second pressure relief channel at a side wall of the housing corresponding to a position of the second chamber, wherein the second pressure relief channel is communicated to the second chamber, and wherein there is disposed a second pressure relief valve in the second pressure relief channel; wherein each of the first pressure relief valve and the second pressure relief valve has a pressure relief rate that is less than a pressure increase rate in the first chamber or the second chamber;
wherein before the plurality of pixel modules are installed, the air pump is configured to be turned on, and the valve assembly is configured to control the first air flow channel and the second air flow channel to be opened, and control the third air flow channel to be closed; wherein after the plurality of pixel modules are installed, the air pump is configured to be turned on, and the valve assembly is configured to control the first air flow channel and the third air flow channel to be opened, and control the second air flow channel to be closed.

6. The display panel as recited in claim 5, wherein there is disposed a receiving groove at the lower part of the housing, wherein the valve assembly is disposed in the receiving groove, wherein the valve assembly comprises a knob, a first rotary piece, a second rotary piece, and a fixing piece; wherein the fixing piece is connected to a groove wall of the receiving groove; wherein the knob is embedded in the fixing piece and is rotatably connected to the fixing piece; wherein a side of the knob adjacent to the second air flow channel is connected to the first rotary piece, wherein a side of the knob adjacent to the third air flow channel is connected to the second rotary piece;
wherein the first rotary piece and the second rotary piece separate the receiving groove to define a first air cavity and a second air cavity, wherein the first air cavity and the second air cavity are disposed opposite to each other, wherein the first air cavity is disposed adjacent to the first air flow channel and is communicated to the first air flow channel;
wherein before the plurality of pixel modules are installed, the knob is operative to drive the first rotary piece to communicate the second air flow channel with the first air cavity, and the second rotary piece is operative to cut off a communication between the third air flow channel and the first air cavity; wherein after the plurality of pixel modules are installed, the knob is operative to drive the second rotary piece to communicate the third air flow channel with the first air cavity, and the first rotary piece is operative to cut off a communication between the second air flow channel and the first air cavity.

7. The display panel as recited in claim 6, wherein there is disposed a first limiting piece on an inner wall of the receiving groove corresponding to a position of the first rotary piece; wherein there is disposed a second limiting piece on the inner wall of the receiving groove corresponding to a position of the second rotary piece;
wherein there is defined a first limiting groove in the first rotary piece corresponding to a position of the first limiting piece; wherein there is defined a second limiting groove in the second rotary piece corresponding to a position of the second limiting piece; wherein the first limiting piece is operative to be embedded in the first limiting groove, and wherein the second limiting piece is operative to be embedded in the second limiting groove; wherein the first limiting groove has a width that is greater than a width of the first limiting piece; wherein the second limiting groove has a width that is greater than a width of the second limiting piece;
wherein when the second air flow channel is communicated to the first air cavity, the first limiting piece abuts against a side of the first limiting groove adjacent to the first air cavity, and the second limiting piece abuts against a side of the second limiting groove adjacent to the second air cavity; wherein when the third air flow channel is communicated to the first air cavity, the first limiting piece abuts against a side of the first limiting groove facing away from the first air cavity, and the second limiting piece abuts against a side of the second limiting groove facing away from the second air cavity.

8. The display panel as recited in claim 7, wherein there is defined a lifting channel in a top of the housing, wherein the lifting channel extends in a direction perpendicular to the substrate;
wherein the lifting rod comprises a supporting piece, a rod body, and an isolating piece; wherein the supporting piece and the isolating piece are respectively connected to two ends of the rod body; wherein the rod body is partially embedded in the lifting channel, and wherein the supporting piece is extended to an outside of the housing; wherein the isolating piece is disposed in the housing, dividing the housing into a first chamber and a second chamber.

9. The display panel as recited in claim 8, wherein the supporting piece and the isolating piece are each a structure in a shape of a plate.

10. The display panel as recited in claim 8, wherein a side of the cover piece facing the plurality of pixel modules is a horizontal flat surface.

11. The display panel as recited in claim 8, wherein the supporting piece and the isolating piece are respectively connected to two ends of the rod body to form an I-shaped lifting rod.

12. The display panel as recited in claim 8, wherein there is disposed a buffer piece at a lower portion of the first chamber, wherein the buffer piece is connected to the inner wall of the housing, wherein when the cover piece covers the plurality of pixel modules, the isolating piece abuts against the buffer piece.

13. The display panel as recited in claim 12, wherein the cover piece comprises a cover plate, wherein the cover plate is made of a light-transmitting material, wherein an orthographic projection area of the cover plate on the substrate is greater than or equal to an orthographic projection area of the plurality of the installation regions on the substrate;
wherein the supporting piece comprises a mounting piece, wherein the cover plate comprises a first connecting piece at a position corresponding to the mounting piece, wherein the mounting piece is connected to the first connecting piece to fix the cover plate to the supporting piece.

14. The display panel as recited in claim 13, wherein each of the at least two lifting devices is detachably connected to the cover plate.

15. The display panel as recited in claim 14, wherein the mounting piece of each of the at least two lifting devices and the corresponding first connecting piece of the cover plate are each a screw hole, wherein the cover plate is fixed to each of the at least two lifting devices by a screw.

16. The display panel as recited in claim 15, wherein the cover plate is made of glass or a plastic having a relatively high light transmittance.

17. The display panel as recited in claim 16, wherein there is arranged a plurality of retaining walls on the substrate, wherein the plurality of retaining walls are arranged in a crisscross pattern to divide the substrate into a plurality of installation regions that are arranged in an array;
wherein there is disposed an installation groove in each of the plurality of installation regions, wherein the installation groove has a shape that matches a shape of each of the plurality of pixel modules, wherein each of the plurality of pixel modules is partially embedded in the respective installation groove;
wherein each of the plurality of retaining walls has a height that is equal to a height of a portion of the respective pixel module exposed from the respective installation groove; wherein after the plurality of pixel modules are installed, the at least two lifting devices are operative to drive the cover piece to abut against a top surface of each of the plurality of retaining walls.

18. The display panel as recited in claim 17, further comprising a hollow cover plate, wherein an orthographic projection area of the hollow cover plate on the substrate is greater than or equal to an orthographic projection area of the plurality of the installation regions on the substrate, wherein the hollow cover plate comprises a through hole corresponding to each of the plurality of installation regions, wherein an area of each through hole is greater than an area of each pixel module;
wherein the hollow cover plate comprises a second connecting piece disposed corresponding to the mounting piece, wherein the second connecting piece is connected to the mounting piece thus fixing the hollow cover plate to the supporting piece; wherein before the plurality of pixel modules are installed, the at least two lifting devices are used to drive the hollow cover plate to rise to a preset height.

19. The display panel as recited in claim 18, wherein the hollow cover plate has a thickness that is less than or equal to a portion of each of the plurality of pixel modules exposed from the substrate.

20. A display device, comprising a rear housing, further comprising a display panel disposed in the rear housing, wherein the display panel comprises a substrate and plurality of pixel modules, wherein the plurality of pixel modules are used for emitting light for display, wherein the substrate is divided into a plurality of installation regions, and wherein each of the plurality of pixel modules is installed in the respective installation region;
wherein the display panel further comprises a pressing structure, wherein the pressing structure comprises at least two lifting devices and a cover piece, wherein the at least two lifting devices are respectively connected to two sides of the substrate;
wherein a top of each of the at least two lifting devices is connected to the cover piece, and wherein the at least two lifting devices are operative to drive the cover piece to rise and fall in a direction perpendicular to the substrate;
wherein in response to the plurality of pixel modules being installed, the at least two lifting devices are operative to drive the cover piece to cover the plurality of pixel modules and abut against the plurality of pixel modules to lie in a same plane so that top surfaces of the plurality of pixel modules are flush with each other.
